(19) United States
(12) Patent Application Publication
(10) Pub. No.: US 2026/0202470 A1
(43) Pub. Date: Jul. 16, 2026

(54) METHOD AND SYSTEM FOR CORRELATING AND FILTERING HIGH-SPEED SIGNAL (HSS) JITTER WITH POWER SUPPLY RIPPLE

(71) Applicant: Tektronix, Inc., Beaverton, OR (US)

(72) Inventors: Madhusudan Acharya, Bengaluru (IN); Shubha B, Bengaluru (IN); Niranjan R. Hegde, Siddapur (IN); Vivek Shivaram, Bengaluru (IN); Krishna N H Sri, Bengaluru (IN)

(73) Assignee: Tektronix, Inc., Beaverton, OR (US)

(21) Appl. No.: 19/447,586

(22) Filed: Jan. 13, 2026

(30) Foreign Application Priority Data
Jan. 14, 2025 (IN) 202521003091
Jan. 14, 2025 (IN) 202521003189

(51) Int. Cl. G01R 31/317; G01R 31/319

(52) U.S. Cl. CPC G01R 31/31709; G01R 31/31721; G01R 31/31912; G01R 31/31919

(57) ABSTRACT

A test and measurement instrument may include a test channel to connect to a device under test (DUT) and analyze signals generated by the DUT. The instrument may include a processor configured to execute code to: measure a first ripple value of a power supply signal from a DUT; measure a first periodic jitter (PJ) value of a high-speed signal, where the high-speed signal is based on the power supply signal; determine a first time interval error (TIE) spectrum from the first PJ value; filter the first TIE spectrum of the first PJ value to receive a second TIE spectrum corresponding to a second PJ value; determine a second ripple value by applying a jitter ratio based on the second PJ value and the first PJ value and a noise factor to the first ripple value; and apply the second ripple value to the power supply signal.

### CROSS-REFERENCE TO RELATED APPLICATIONS

This disclosure claims priority under 35 U.S.C. § 119 to Indian Provisional Patent Application No. 202521003189, titled “METHOD AND SYSTEM FOR CORRELATING HIGH-SPEED SIGNAL (HSS) JITTER WITH POWER SUPPLY RIPPLE,” filed on Jan. 14, 2025, and to Indian Provisional Patent Application No. 202521003091, titled “CUSTOMIZABLE AND INTELLIGENT PERIODIC NOISE FILTER FOR PRECISE CORRELATION OF POWER SUPPLY RIPPLE WITH HIGH-SPEED SIGNAL JITTER,” filed on Jan. 14, 2025, the disclosure of each is incorporated herein by reference in its entirety.

### TECHNICAL FIELD

Examples of the present disclosure generally relate to the field of signal integrity (SI) and power integrity (PI) in high-speed electronic systems. More particularly, it pertains to methods and systems for correlating high-speed signal jitter components with power supply ripple, and filtering thereof.

### BACKGROUND

Managing power supply noise is critical in ensuring the stability and performance of modern electronic systems. Power supply noise, including voltage ripple and electromagnetic interference, can significantly impact the performance of high-speed electronic components, leading to instability and degradation of signal integrity. In high-speed digital systems, signal integrity (SI) and power integrity (PI) are critical considerations to ensure reliable data transmission and system performance. SI analysis focuses on the performance of the transmitter, reference clock, channel, and receiver in terms of bit error rate (BER).

On the other hand, PI addresses the ability of the power delivery network (PDN) to provide stable voltage power rails and low-impedance return paths. Voltage ripple in a power distribution network (PDN) arises from high-frequency noise, which can lead to periodic voltage variations. These variations can adversely affect the stability of power supply to sensitive components. Improperly impedance-matched PDNs exhibit resonant and anti-resonant peaks, resulting in large voltage spikes at specific frequencies, compounding the issue of power supply noise. Additionally, power lines often act as unintended antennas, radiating electromagnetic interference that further deteriorates system performance.

These two domains (SI and PI) are closely interlinked, as noise and ripple in the power supply can significantly impact signal quality by introducing jitter components into the high-speed signal.

The interaction between SI and PI is a well-known phenomenon, where the PDN's impedance characteristics, circuit design, and components such as chip packages, pins, traces, vias, and connectors contribute to noise propagation and jitter generation. While tools for jitter analysis have addressed portions of this challenge, existing solutions fail to provide comprehensive tools for analyzing and mitigating the impact of power supply noise on jitter in high-speed signals and they fall short in enabling precise user control over the filtering process and correlating the extent of ripple reduction to changes in jitter. Designers lack the capability to determine how a specific percentage reduction in power supply ripple translates to improvements in jitter components, making it difficult to optimize power supply designs under practical constraints.

Currently, power supply designers often test HSS performance using worst-case ripple scenarios, where high ripple noise is injected into the power rails to observe the resultant jitter. However, this approach fails to provide insights into the degree of jitter suppression achievable through specific design refinements or notch filtering. These filters are designed to remove specific frequency components from a signal. However, these filters primarily focus on horizontal frequency ranges and are constrained by hardware limitations such as finite Q-factor and non-linear phase responses. These shortcomings limit their effectiveness in accurately emulating PDN circuit behavior, thereby hindering the precise correlation of power supply ripple with jitter components. Furthermore, there is no comprehensive solution that correlates jitter in the frequency domain with ripple in the time domain. This gap in existing technology presents significant challenges for optimizing PDN designs to meet the stringent requirements of high-speed systems.

### BRIEF DESCRIPTION OF THE DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 illustrates a ripple stress setup for High-Speed Signal (HSS) loads at development and testing stage, in accordance with the present disclosure.

FIG. 2 illustrates effect of power and ground voltage fluctuations for the low-to-high output transition, in accordance with the present disclosure.

FIG. 3 illustrates clock path from PLL to output buffer, in accordance with the present disclosure.

FIG. 4 illustrates classification of jitter into different components, in accordance with the present disclosure.

FIG. 5 illustrates the DC ripple impact on HSS Jitter caused by power supply, in accordance with the present disclosure.

FIG. 6 illustrates measurement configuration for power and HSS sources with Notch filter, in accordance with the present disclosure.

FIGS. 7A and 7B are flowcharts illustrating operations to reduce ripple, in accordance with the present disclosure.

FIG. 8 illustrates the ripple performance test, in accordance with the present disclosure.

FIGS. 9A-E illustrates the results of the ripple performance test, in accordance with the present disclosure.

FIG. 10 illustrates a high-level representation of PDN circuit, in accordance with the present disclosure.

FIG. 11 illustrates a Twin-T Notch filter, in accordance with the present disclosure.

FIG. 12 illustrates a HW Notch filter with different Q values, in accordance with the present disclosure.

FIG. 13 illustrates the filter levels of HSS Jitter, in accordance with the present disclosure.

FIG. 14 illustrates measurement configuration with Auto and Custom ripple adjustment and 2D filters, in accordance with the present disclosure.

FIG. 15 is a flowchart illustrating operations to vertically filter a power supply signal having ripple for correlating power supply ripple with high-speed signal jitter, in accordance with the present disclosure.

FIG. 16A-F illustrates the Vertical Filter impact on controlled PJ reductions, in accordance with present disclosure.

To facilitate understanding, identical reference numerals have been used, where possible, to designate identical elements that are common to the figures. It is contemplated that elements of one example may be beneficially incorporated in other examples.

### DETAILED DESCRIPTION

In the following description, for purpose of explanation, specific details are set forth in order to provide an understanding of the present disclosure. It will be apparent, however, to one skilled in the art that the present disclosure may be practiced without these details. One skilled in the art will recognize that implementations of the present disclosure, some of which are described below, may be incorporated into a number of systems.

The systems and methods are not limited to the specific implementations described herein. Further, structures and devices shown in the figures are illustrative of exemplary implementations of the present disclosure and are meant to avoid obscuring of the present disclosure.

References in the present disclosure to “an implementation” or “another implementation” mean that a particular feature, structure, characteristic, or function described in connection with the implementation is included in at least one implementation of the disclosure. The appearances of the phrase “in an implementation” in various places in the specification are not necessarily all referring to the same implementation. The phrase “implementation of the present disclosure” used in the present disclosure may refer to various embodiments of the present disclosure.

This disclosure introduces a novel approach that not only correlates jitter parameters to ripple in the time domain for real-time analysis and optimization but also leverages advanced vertical filtering techniques to control periodic jitter (PJ) reductions, together providing a comprehensive and interactive solution for high-speed signal integrity and power integrity co-design.

The approach of the present disclosure can correlate jitter parameters to ripple in the time domain, enabling a completely new approach to analyzing and optimizing high-speed signal performance. Unlike existing solutions that only emulate filtered jitter components, the proposed method allows for real-time visualization of ripple reduction effects and computes the updated ripple waveform, providing unparalleled insights into the design process. Furthermore, the present disclosure incorporates advanced algorithms and user interfaces, enabling designers to emulate and analyze jitter values at various stages of hardware refinement. This includes the ability to analyze the combined effects of multi-rail scenarios and apply notch filtering to dominant ripple frequencies, offering a comprehensive solution for PI and SI co-design challenges.

The present disclosure describes a method for correlating jitter components, such as periodic jitter (PJ), with power supply ripple. By correlating jitter components to power supply ripple, the present disclosure involves correcting for the jitter components and thus reducing ripple. The present disclosure introduces a customizable and intelligent periodic noise filter that incorporates both horizontal and vertical filtering. Vertical filtering enables designers to quantify jitter suppression in relation to power supply ripple, providing insights for effective design improvements. The present disclosure also leverages an advanced emulation algorithm that automatically detects multiple power rails contributing to jitter in high-speed signals. By applying optimized 2D filtering in both horizontal and vertical dimensions, the system achieves precise ripple suppression, closely emulating the effects of hardware designs. The present disclosure utilizes real-time time-domain waveforms of power rails and high-speed signal loads, iteratively optimizing the filter settings to achieve the desired ripple outcomes.

Moreover, the present disclosure provides an advantage over traditional hardware filters by offering a brick-wall Fast Fourier Transform (FFT)-based filtering mechanism, ensuring more precise and linear-phase responses. This capability bridges the gap between software emulation and hardware implementation, allowing for accurate correlation and optimization of power supply ripple and jitter components. In addition to its novel filtering methodology, the invention emphasizes the importance of effective bypassing and decoupling techniques to improve power supply signal integrity. By incorporating low-inductance, high-capacitance decoupling components, the system ensures reliable operation and enhanced stability. These considerations are integral to the invention's approach, offering designers a comprehensive toolset to address power supply noise challenges. Through its innovative design and methodology, the present disclosure offers significant advantages over prior solutions, enabling precise correlation of power supply ripple with high-speed signal jitter, thus paving the way for more robust and efficient electronic systems.

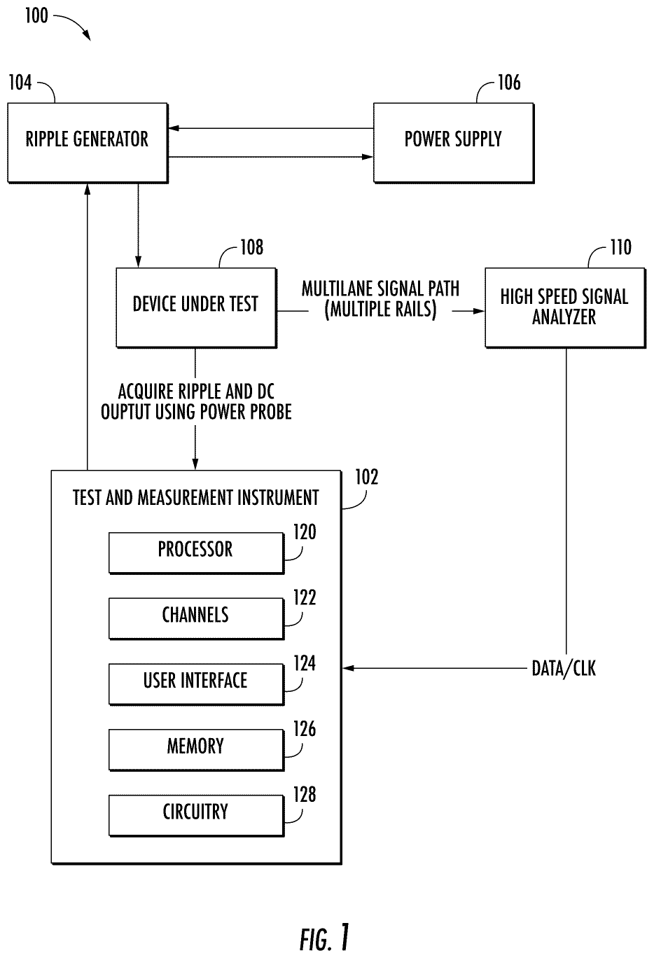

FIG. 1 illustrates a ripple stress setup for High-Speed Signal (HSS) loads at development and testing stage, in accordance with the present disclosure. This figure demonstrates the experimental setup used for inducing ripple stress on power rails connected to HSS loads during the development and testing stages. The test setup of FIG. 1 also can be used for jitter suppression testing for multiple rails as it provides a HSS jitter profile as a function of power supply ripple. The setup highlights how periodic variations in the power supply ripple correlate with jitter amplitude.

The setup 100 comprises a ripple generator 104, a power supply 106, a test and measurement instrument 102, a device under test (DUT) 108 and a high-speed signal (HSS) analyzer 110. As illustrated, the power supply 106 and the ripple generator 104 are coupled so that the ripple generator 104 modulates the power supply 106, creating controlled ripple patterns in a power supply signal from the power supply 106. This setup 100 helps evaluate the impact of ripple on signal quality by observing variations in jitter components of the HSS output. The power supply 106 can be a signal generator, a constant voltage power supply, or any other type of power source. The ripple generator 104 can be an arbitrary function generator, an arbitrary waveform generator, or any other generator that can inject a ripple into a signal.

The ripple generator 104 sends the power supply signal with ripple to the DUT 108. In some examples, the DUT 108 can be power rails under test, or any other type of component under test, such as a Picotest VRTS3 demo board which generated HSS with 125 MHz frequency. The DUT 108 is coupled to the high-speed signal analyzer 110 via a multi-lane signal path. In some examples, the multi-lane signal path comprises multiple rails between the DUT 108 and the HSS analyzer 110. The HSS analyzer 110 can be any receiver circuit.

The DUT 108 is also coupled to the test and measurement instrument 102. The test and measurement instrument 102 acquires ripple and DC output using a power rail probe coupled to one or more channels 122 of the test and measurement instrument 102. The ripple and DC output from the DUT 108 can be referred herein as the power supply signal, as this signal from the DUT 108 that needs correlation to high-speed signal jitter. In examples in which the DUT 108 comprises multiple rails, the DUT 108 is coupled to the test and measurement via the multiple rails and the one or more channels.

The test and measurement instrument 102 is also coupled to the HSS analyzer 110 and receives data and/or clock signals from the HSS analyzer 110. With the DC output from the DUT 108 and the data/CLK signals from the HSS analyzer 110, the test and measurement instrument 102 can then correlate jitter domain to ripple in time domain.

As illustrated, the test and measurement instrument 102 can suppress jitter and estimate reduced PJ and its associated ripple values. If the ripple values are not the desired ripple values, then appropriate hardware changes can be made or changes to the ripple generator 104 can be made. In such examples, changes to the ripple generator 104 involve changing the parameters for the ripple injected into the signal from the power supply 106. Further the test and measurement instrument 102 can apply a vertical filter to further reduce ripple as described herein. The amount of filtering needed in emulation gives an indication of the amount of filtering needed in hardware.

The test and measurement instrument 102 also includes a processor 120, memory 126, circuitry 128, channels 122, and a user interface 124. The test and measurement instrument 102 can be a scope or any other type of test and measurement instrument. The test and measurement instrument 102 can also include ports (not illustrated) coupled to the channels 122 of the test and measurement instrument 102. The ports and channels 122 may be any electrical signaling medium, and may include receivers, transmitters, and/or transceivers.

One or more processors 120 may be configured to execute instructions from memory and may perform any methods and/or associated steps indicated by such instructions, including measuring a first ripple value from a power supply signal from the DUT 108, measuring a first PJ value (which can be the original PJ value) from a high-speed signal from the HSS analyzer 110, filter the first PJ value to get a second PJ value (which can be the emulated PJ value), determine a second ripple value by applying a jitter ratio, and apply the second ripple value to the power supply signal. These instructions implements correlation of high-speed jitter with power supply ripple and reduction thereof. The one or more processors 120 may be configured also to execute instructions from memory and may perform any methods and/or associated steps indicated by such instructions, including acquiring a power supply signal and a high-speed signal, generating and applying a vertical filter based on a frequency range of the high-speed signal, and reconstructing a filtered power supply signal from the vertically-filtered high-speed signal to correlate the jitter of the high-speed signal to the ripple of the power supply signal. These instructions implements a vertical filter of the power supply signal having ripple for correlating power supply ripple with high-speed signal jitter.

Memory 126 or any other memory on the test and measurement instrument 102 may be implemented as processor cache, random access memory (RAM), read only memory (ROM), solid state memory, hard disk drive(s), or any other memory type. Memory acts as a medium for storing data, computer program products, and other instructions.

User interface 124 is coupled to the one or more processors 120. User interface 124 may include a keyboard, mouse, trackball, touchscreen, and/or any other controls employable by a user to interact with a GUI on the display (not illustrated). The display may be a digital screen or any other monitor to display waveforms, measurements, and other data to a user.

While the components of the test and measurement instrument 102 are depicted as being integrated within the test and measurement instrument 102, it will be appreciated by a person of ordinary skill in the art that any of these components can be external to the test and measurement instrument 102. The components may couple to the test and measurement instrument 102 in any conventional manner, such as wired and/or wireless communication media and/or mechanisms. For example, in some examples, the display (not illustrated) may be remote from the test and measurement instrument 102.

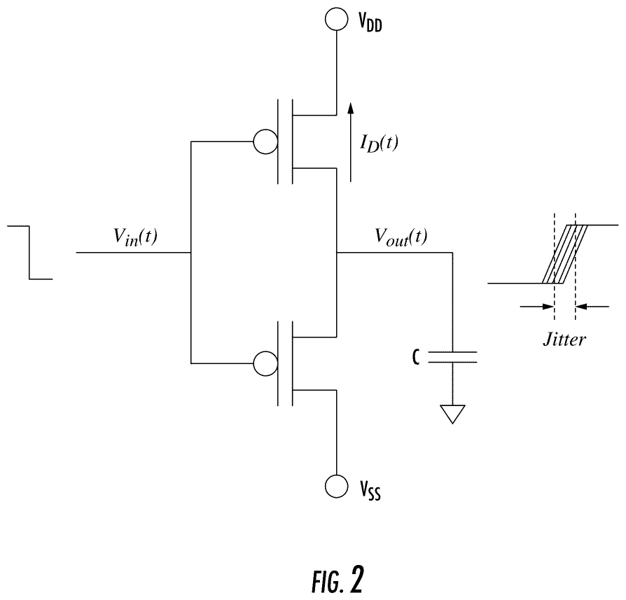

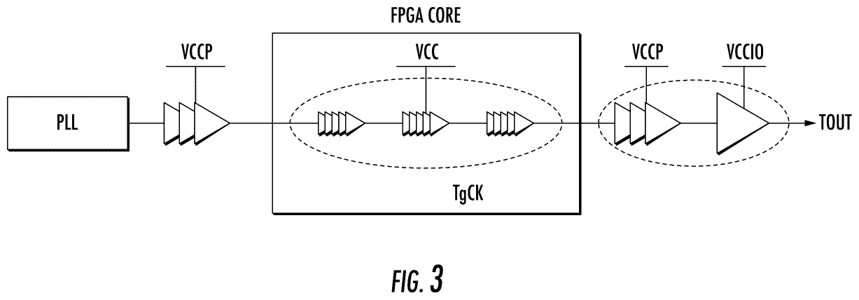

FIG. 2 illustrates effect of power and ground voltage fluctuations for the low-to-high output transition, in accordance with the present disclosure. FIG. 2 illustrates the impact of voltage fluctuations on the low-to-high transition of output signals and shows the variations in power supply voltage VDD(t) and ground voltage VSS(t), modelled as sinusoidal components superimposed on DC levels. These fluctuations manifest as ripples, impacting the timing characteristics of the signal and causing higher jitter in the HSS loads. For a given output transition event, the power and ground voltages, including fluctuations, are represented by the following equations:

$$VDD ( t , ts ) = VDD + Vnp cos ( w ( ts + t ) + ∅ p )$$

$$VSS ( ts ) = Vss + Vng cos ( wts + ∅ g )$$

where VDD is the power level, VSS is the ground bias level, Vnp and Vng are the power and ground voltage fluctuations. Øp and Øg are the initial phases of the power and ground voltage fluctuations, respectively. The cosine part in these equations represents sinusoidal variations, typical in simulations, while actual hardware fluctuations can be random. These fluctuations appear as ripples in the power supply, which subsequently increase jitter in HSS signals.

For the measurement of Clock (CLK) Power Supply Induced Jitter (PSIJ), different clock routing paths are designed in the hardware of the test and measurement instrument 102. Generally, all designs use the same clock phase-locked loop (PLL) source and output buffer to compare only the clock routing length effect.

FIG. 3 illustrates clock path from PLL to output buffer, in accordance with the present disclosure. This figure outlines the flow of the clock signal, starting from the PLL and passing through the global clock network to the output buffer. Accordingly, the exemplary clock path emphasizes the points where jitter can be introduced due to variations in clock routing length, power rail noise, or output driver impedance. The clock path is a critical part of jitter analysis, as any noise along this route propagates to the high-speed signals.

Power rail noise, often called ripple, is typically a few millivolts. Accurate measurements of mV noise on a power rail at GHz frequencies requires high bandwidth probes with high DC impedance that act as 50Ω transmission lines at high frequencies. Switch-mode power supplies (SMPS) regulate the voltage between the power rail and the return path (ground) by continuously switching between low dissipation on and off states. Unfortunately, the pulses that drive the switching elements can induce switching noise and hence cause PJ.

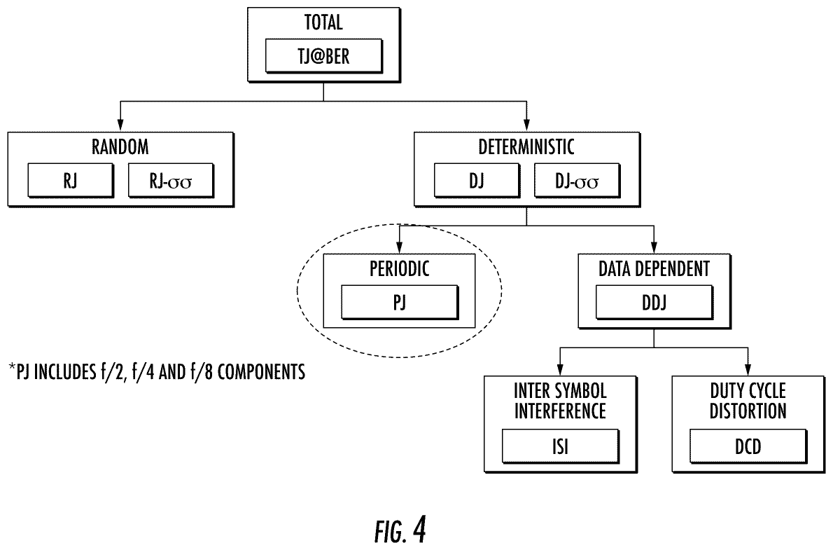

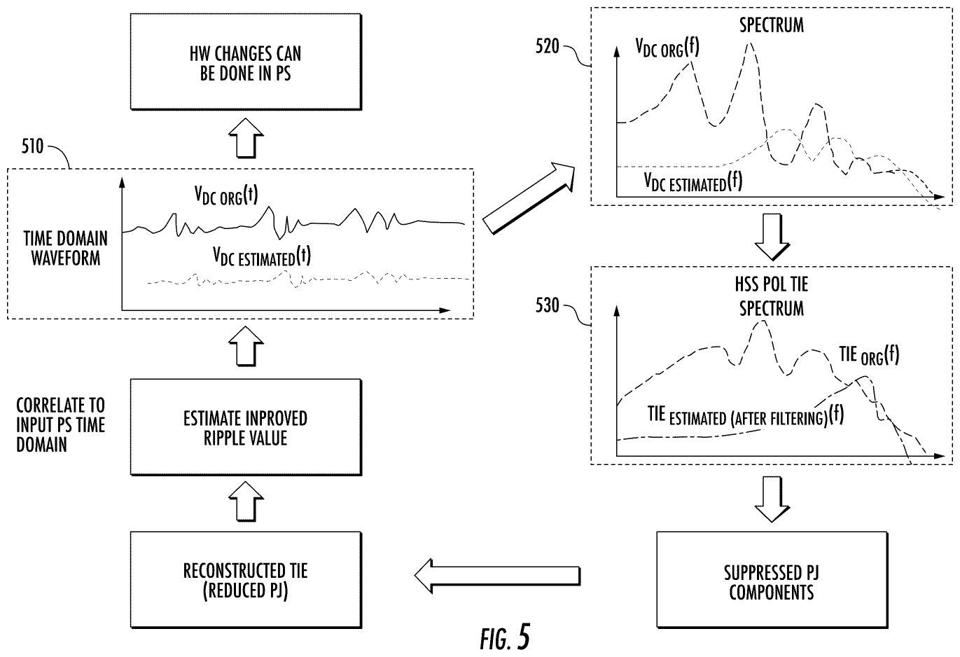

FIG. 4 illustrates classification of jitter into different components, in accordance with the present disclosure. This figure provides a detailed breakdown of jitter into its primary categories. The Total Jitter (TJ) is the combined jitter observed in the system. The Deterministic Jitter (DJ) includes PJ and data-dependent jitter (DDJ). The Random Jitter (RJ) is the noise-induced jitter with a Gaussian distribution. The figure graphically represents how jitter components are separated and analyzed to identify their sources and effects on overall signal quality. The separation of these components provides a detailed view of how various noise sources contribute to jitter in high-speed signals.

The jitter estimation process considers the relationship between the input switching frequency and the frequency components of the supply voltage fluctuations by sampling the Timing Interval Error (TIE) at each switching time. The transfer function of the supply fluctuation with frequency f to jitter, normalized by the fluctuation amplitude, is calculated using the following equation:

$$\vert {H}_{jitter} ( f ) \vert = \vert \frac{Jitter}{{V}_{n 0}} \vert = \frac{1}{{V}_{DD 0}} \frac{C}{0.5 λ + {G}_{m}} \frac{( λ + {g}_{m} )}{{λ}^{2} + {C}^{2} {ω}^{2}} \times \sqrt{( 1 + {( \frac{0.5 λ + {G}_{n}}{λ + {G}_{m}} )}^{2} - 2 cos ( ω {t}_{pLH} ) \frac{0 . S λ + {G}_{m}}{λ + {G}_{m}} )}$$

where Vₙ₀ is the supply voltage fluctuation amplitude, V_{DD0} is the bias level, C is the loading capacitor, Gₘ and gₘ are the large-signal and small-signal gains, respectively, λ is a parameter defining the system impedance, and t_{pLH} is the perturbation voltage. This equation models the relationship between supply noise and jitter, applicable during simulations.

The voltage noise model is derived from system-level power delivery network modeling and current profile generation. Switching frequencies are recorded from the DC-to-DC converter data sheet, and ripple spectrum analysis identifies spurs at switching frequencies or harmonics. These spurs are visualized in the TIE histogram and TIE spectrum, revealing PJ distribution characteristics.

FIG. 5 illustrates the DC ripple impact on HSS Jitter caused by power supply, in accordance with the present disclosure. This figure illustrates the relationship between DC ripple on the power rail shown in box 520 and the jitter observed in the HSS signal shown in box 530. It shows the propagation of ripple-induced noise from the power rail through the circuit, culminating in an increase in PJ within the high-speed signal. The figure visualizes how ripple magnitude and frequency correlate with jitter components.

If the ripple spectrum of the input-side power supply, as depicted in box 520, and its corresponding TIE spectrum, also shown in box 530, both exhibit spurs at the switching frequencies or harmonics thereof, the origin of these spurs can be identified and subsequently mitigated through appropriate hardware design modifications. As illustrated in box 530 of FIG. 5, the TIE spectrum of the high-speed serial (HSS) clock signal emphasizes the PJ component that is directly attributable to ripple present in the power supply, as detailed in box 510. This approach enables targeted analysis and correction of spur sources to improve overall signal integrity within the system.

Further by reducing PJ and generating improved ripple values, the present disclosure involves correlating the improved ripple values to the power supply waveform (shown in box 510) and thus making changes to improve signal integrity and power integrity.

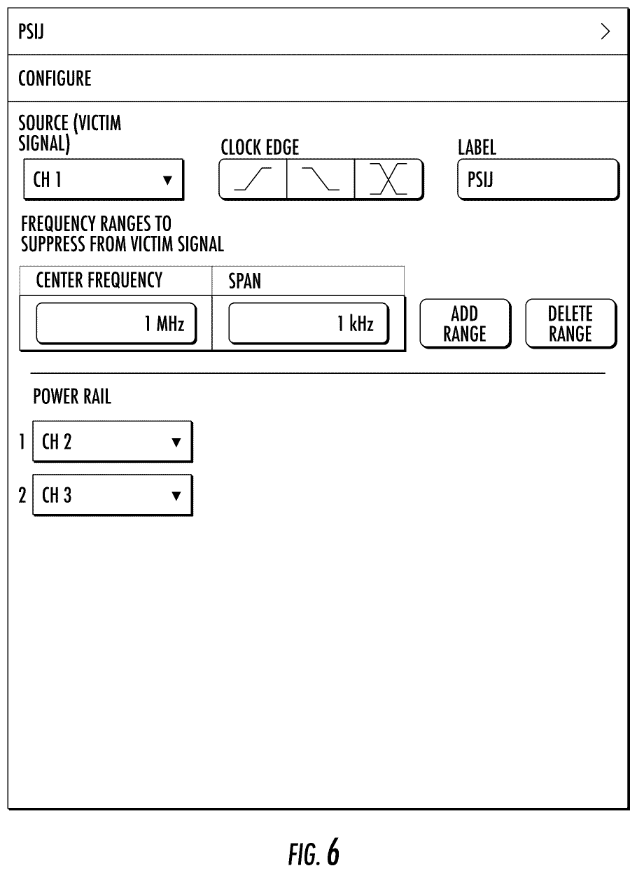

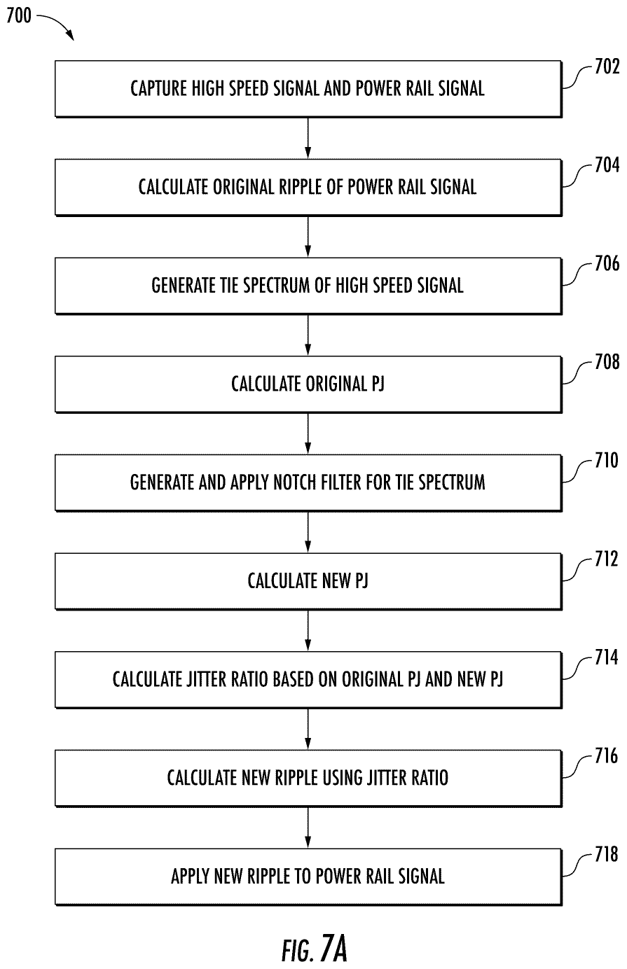

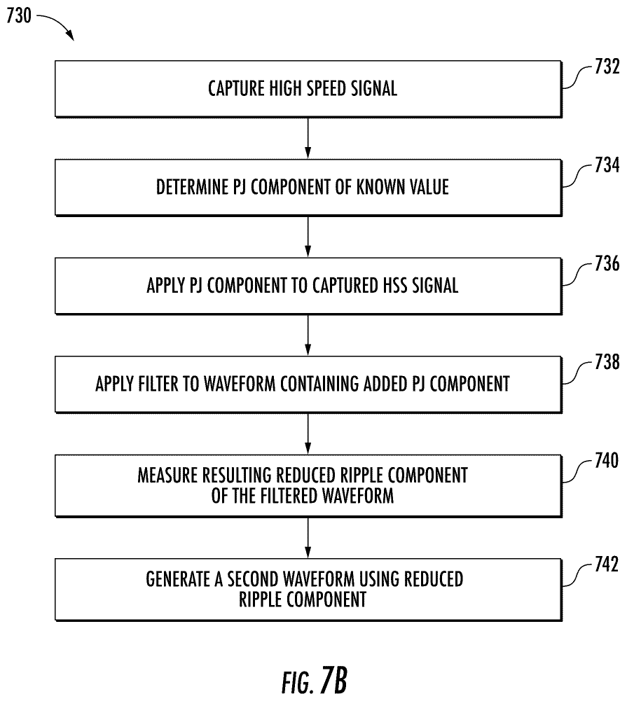

FIG. 6 illustrates measurement configuration for power and HSS sources with Notch filter on a test and measurement instrument, in accordance with the present disclosure. While FIG. 6 illustrates the configuration using a notice filter, the present disclosure can use other types of filters and is not limited to notch filters. Further, FIG. 6 shows the experimental configuration for measuring the impact of ripple on HSS jitter using a notch filter. The present disclosure can use other configurations of measuring the impact of ripple on HSS jitter using other types of filters. This figure illustrates the measurement setup for capturing ripple values and their reduction percentages using a notch filter configuration. The measurement takes two sources: the power supply signal, and the high-speed signal. The measurement also takes in the percentage reduction in ripple, for computation.

From the entered sources and reduction percentages, the final ripple value is shown in the configuration panel, enabling users to fine-tune the reduction percentage. The number of power rails supported depends on the number of channels for the test and measurement instrument.

The power source is the aggressor, while the HSS acts as the victim. For multi-rail scenarios, each DC power rail output is captured by a separate channel of the test and measurement instrument. The combined effect of multiple rails acts as multiple aggressors, impacting the designated victim through cross-talk between the rails. Internally, the FFT of the power supply signal is used to identify the ripple frequency. Since ripple follows a linear relationship, the ripple reduction percentage is applied to the dominant frequency in the FFT to compute the emulated ripple (peak-to-peak):

$$New Ripple Value = f ( Actual Jitter , Filtered Jitter , Original Ripple )$$

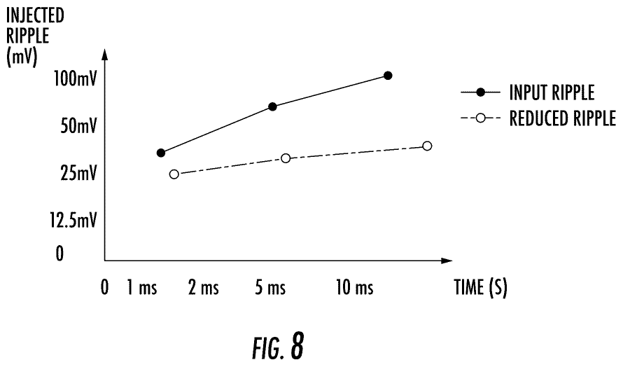

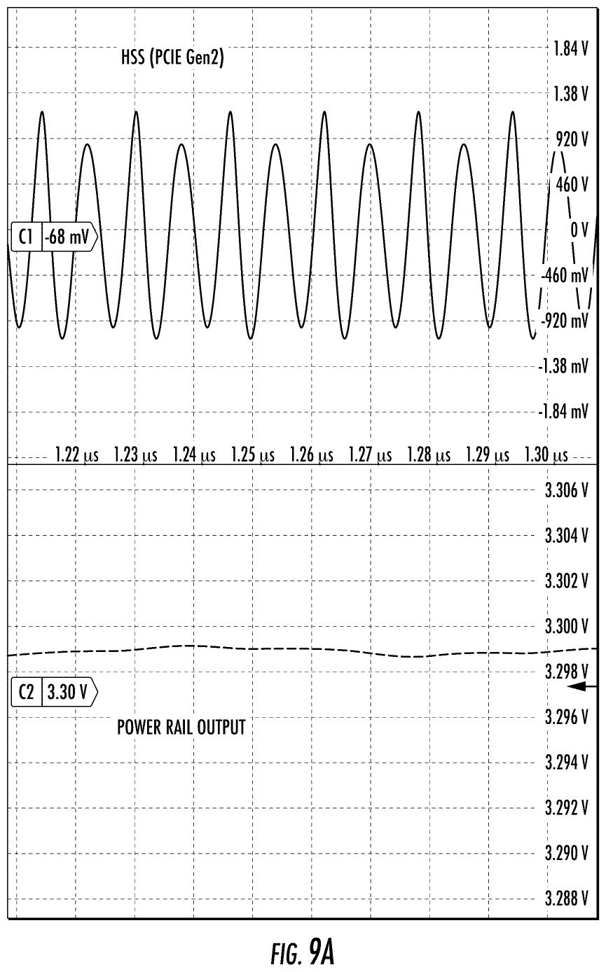

FIG. 7A and FIG. 7B are flowcharts illustrating operations for ripple reduction, according to the present disclosure. The operations 700 of FIG. 7A and operations 730 of FIG. 7B for ripple reduction may be performed by a test and measurement instrument, such as test and measurement instrument 102 of FIG. 1.

In some examples, a user of a test and measurement instrument, such as an oscilloscope, initiates the ripple reduction as described in operations 700. In some examples, the ripple reduction may start at 702 with capturing the high speed signal and power rail signal. In some examples, the test and measurement instrument (e.g., test and measurement instrument 102 of FIG. 1) captures the high speed signal from a load device (e.g., high speed signal analyzer 110 of FIG. 1) and the power rail signal from a DUT (e.g., DUT 108 of FIG. 1).

Operations 700 continues with determining a first ripple value, which may be referred to as the original ripple value (RippleOrg), from the power supply rail at 704.

Operations 700 continues with generating the TIE spectrum of the high speed signal at 706.

Operations 700 continues at 708 with calculating the original PJ (PJOrg). In some examples, calculating the original PJ may involve calculating the actual root mean square (RMS) value of the periodic jitter.

Operations 700 continues at 710 with generating and applying a notch filter for the TIE spectrum of the high speed signal.

Operations 700 continues at 712 with calculating and/or measuring the the resulting notch-filtered jitter value (PJNew).

Operations 700 continues at 714, in which to quantify the effectiveness of the filtering, a jitter ratio is computed as the quotient of the filtered jitter and the original jitter:

$$Jitter ratio : Jitter Ratio = PJNew / PJOrg ;$$

In some examples, operations 700 continues to 716, in which a second ripple value, which may be referred to as the new ripple value (RippleNew), is determined by multiplying the jitter ratio by a pre-computed normalization factor ‘k’—which accounts for scope floor noise, system noise, and other measurement artifacts—and by the original ripple value (RippleNew=JitterRatio×k×RippleOrg).

In some examples, at 718, the new ripple value (also referred to as the second ripple value) is applied to the power supply signal.

In some examples, with the second ripple value, changes to the hardware or to the setup (as shown in FIG. 1) may be made based on the second ripple value

The normalization factor ‘k’ incorporates contributions from the oscilloscope, probe, connection, offset, and similar sources, thereby ensuring accurate estimation of ripple reduction. Operations 730 of FIG. 7B also show how to compute the normalization factor ‘k’. As illustrated, at 732, the test and measurement device captures a high-speed serial (HSS) clock signal. The HSS clock signal can be captured from or generated by the HSS analyzer 110 of FIG. 1.

At 734, a known PJ component is then synthesized and, and, at 736, superimposed onto the previously obtained HSS waveform.

Next, at 738, a notch filter is applied to the waveform containing the added PJ, and the resulting reduced ripple component is measured.

At 740, the ripple component associated with this augmented waveform is subsequently recorded.

At 742, a new waveform is then constructed using the PJ value obtained from the previous step, and its corresponding ripple component is documented.

The PJ values from the original and filtered waveforms should ideally be equal, resulting in a ratio of one, which theoretically defines the normalization factor ‘k’. However, empirical analysis reveals that the actual value of ‘k’ is typically less than one, reflecting the influence of system noise and other sources of error when compared to the injected noise. Accordingly, in some examples, the normalization factor ‘k’ is pre-computed to account for these effects and is incorporated within the software application as part of the overall measurement and analysis methodology.

The operations 700 of FIG. 7 ensures precise ripple estimation, allowing users to confidently mitigate ripple effects and refine their designs.

FIG. 8 illustrates the ripple performance test conducted to analyze the impact of ripple on high-speed signals, in accordance with present disclosure. As illustrated, the plot of FIG. 8 shows the input ripple values at three different times generated by the ripple generator 104 of FIG. 1 and the corresponding estimated ripple values. As shown in FIG. 8, the estimated ripple values are lower than the injected ripple values after emulation, achieved by applying a notch filter. Once the ripple level is properly set, the approach of the present disclosure involves converting this percentage ripple level into the TIE spectrum domain. Based on this level, filtering in the TIE spectrum is performed. The width of the filtering window can be adjusted based on the signal input or set as a percentage of the ripple frequency. This approach assumes a single dominant ripple frequency, resulting in a single filter in the TIE spectrum. If the ripple frequency includes harmonics, those harmonics can be removed with multiple filters. However, the dominant frequency remains singular, which distinguishes this method from the existing PSIJ measurement techniques.

Table 1 shows the ripple profile showing the reduced jitter and the reduced ripple using the proposed methodology.

TABLE 1

| DC Voltage, Ripple | Jitter (PJ) | Ripple (estimated) |
|---|---|---|
| (Injector) | reduced | reduced |
| 3.0 V, 10 mV | 20 ps | 4 mV |
| 3.0, 25 mV | 25 ps | 5 mV |
| . . . | . . . | . . . |

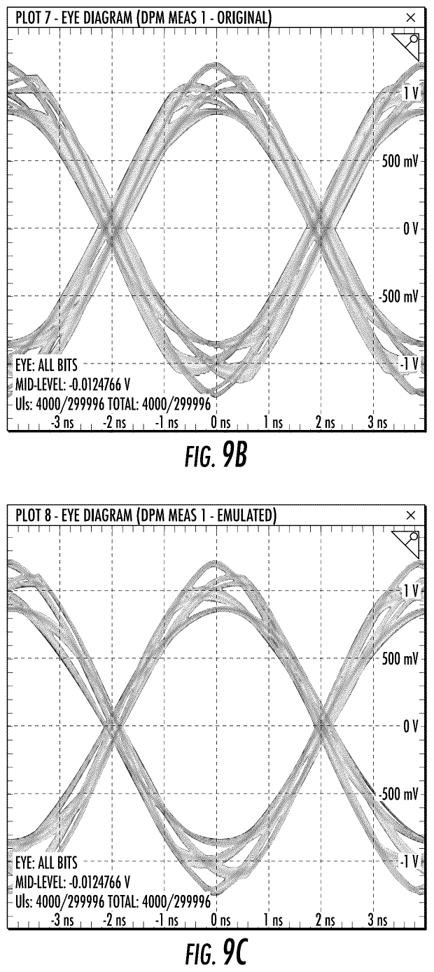

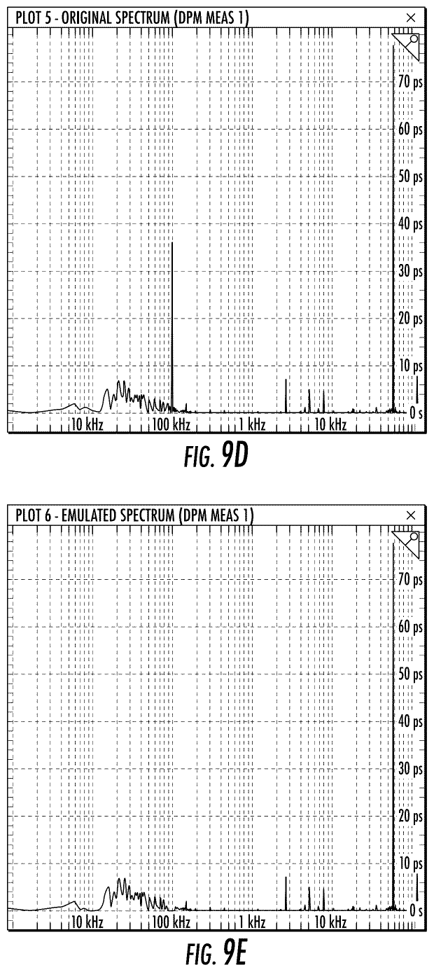

FIGS. 9A-D illustrates the results of the ripple performance test, in accordance with present disclosure. These figures illustrate the results of the ripple performance test, emphasizing the effect of notch filtering on ripple reduction. A notch filter was applied at 10 KHz and 98 KHz with a span range of 5 kHz and 25 kHz for the waveform under test. FIG. 9A shows two waveforms according to the present disclosure. The top waveform shows PCIE Gen 2 High Speed Serial waveform with Jitter before PSIJ Emulation and is the waveform input to PSIJ emulation described herein. The bottom waveform of FIG. 9A is the power Rail waveform of PCIE Gen 2 Load, which is also waveform input to PSIJ emulation described herein. FIG. 9B is an eye Diagram of PCIE Gen 2 High Speed Serial waveform before PSIJ emulation. FIG. 9C is an eye diagram of PCIE Gen2 High Speed Serial waveform PSIJ Emulation. FIG. 9D is a plot showing the TIE spectrum of PCIE Gen 2 High Speed Serial waveform before PSIJ Emulation. FIG. 9E is a plot showing the TIE Spectrum after PSIJ Emulation.

Table 2 shows measurement results with and without the PSI emulation, as described herein. The measurement results provide a comparative analysis between original data and emulated data, indicating enhanced performance. Furthermore, frequency of the PCIe Gen 2 waveform measured to be 125.1 MHz to substantiate the improvements described.

TABLE 2

| | |
|---|---|
| Original | Emulated |

| | | | | |
|---|---|---|---|---|
| TIE | 133.7 | ps | 98.85 | ps |
| PJ | 526.8 | ps | 352.0 | ps |
| Eye Height | 932.0 | mV | 960.9 | mV |
| Eye Width | 3.121 | ns | 3.105 | ns |

To further clarify the ripple and jitter correlation observed in the test results of Table 1, the following specific measurements were obtained. Initially, the original period jitter (PJOrg) was measured at 1.159 ns. After applying the notch filter, the new period jitter (PJNew) was reduced to 802.6 ps. The corresponding ripple on the power rail, measured peak-to-peak, decreased from 15.40 mV (or 3.299 mV RMS) to 10 mV peak-to-peak (2.285 mV RMS), calculated using the determined jitter ratio and a scaling factor (Jitter Ratio: PJNew/PJOrg=0.6925; RippleNew (peak-to-peak): 0.6925×0.98×15.40 mV=10 mV). These quantitative results illustrate the direct relationship between ripple suppression and periodic jitter reduction, substantiating the effectiveness of the proposed filtering and correlation method.

These results demonstrate how the ripple on the power rail is reduced based on PJ jitter suppression. Users can observe this backward correlation, which provides valuable insights and confidence for improving power supply designs. This figure summarizes the outcomes of the ripple performance test, presenting a graphical representation of ripple levels and corresponding jitter values. It shows how reducing ripple leads to a proportional reduction PJ and highlights the effectiveness of the proposed correlation method. The results validate the capability of the system to quantify ripple impact and assist in optimizing PDN designs.

The advantages of the present disclosure are provided herewith. The present disclosure introduces an approach that correlates jitter domain parameters with ripple in the time domain. This approach allows users to observe how incremental reductions in power supply ripple affect high-speed signal jitter, providing actionable insights for PDN optimization. It further enables precise control over the extent of filtering in the jitter domain, allowing for customizable analysis based on specific design requirements. This method computes the updated ripple waveform and provides a backward correlation mechanism that relates jitter suppression to power supply ripple reduction. This method accommodates multi-rail scenarios by considering the combined effects of multiple aggressors on a single victim signal. This method assists designers in understanding and addressing practical constraints, such as reducing rather than eliminating ripple components.

As mentioned earlier, the present disclosure also includes a customizable and intelligent periodic filter that enables quantifying jitter suppression in relation to power supply ripple. The filter described herein allows for both horizontal and vertical filtering.

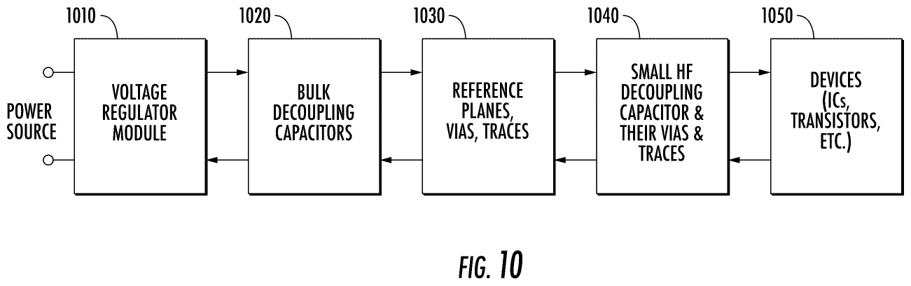

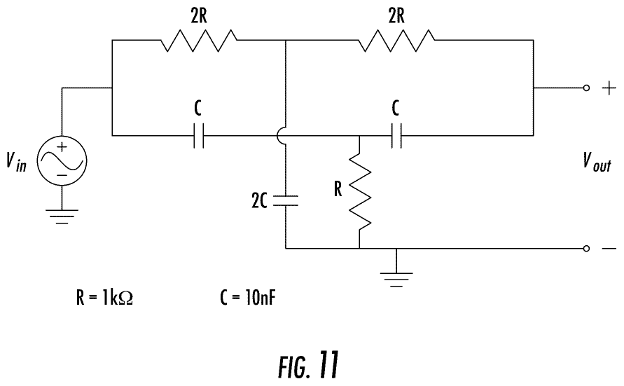

FIG. 10 illustrates a high-level representation of PDN circuit, in accordance with the present disclosure. This diagram illustrates a typical power distribution network (PDN), showing the interaction between power supply components, such as the voltage regulator module 1010, bulk decoupling capacitors 1020, connectors 1030 (such as reference planes, vias, and traces), small decoupling capacitors and connectors 1040 (such as vias and traces), and the connected electronic load 1050 (such as integrated circuits, transistors, and others). Accordingly, this high-level representation of a PDN circuit shows the impedance spectrum of the PDN, identifying resonant and anti-resonant peaks that lead to voltage ripple and power supply noise.

Proper bypassing and decoupling techniques improve overall power supply signal integrity, which is important for reliable design operation. These techniques become more significant with increased power supply current requirements as well as increased distance from the power supply to the point-of-load (generally the FPGA or CPLD device). The type of bypassing and decoupling techniques depends on the system design and board requirements. Target PDN impedance and ripple voltage are functions of capacitance, so once users observe an enhancement in ripple (PJ) values, they are inclined to select capacitors of appropriate size and value to ensure optimal performance.

FIG. 11 illustrates a Twin-T Notch filter, in accordance with the present disclosure. The schematic of a hardware-based notch filter is presented here, showing the configuration of resistors and capacitors to achieve specific frequency rejection. The diagram also includes annotations for the placement of input and output probes, which are used to measure the filter's performance.

As illustrated in FIG. 11, a first probe from a test and measurement instrument can be attached to the input of the circuit (Vin) via a power supply (such as power supply 106 or ripple generator 104) and a second probe from a test and measurement instrument (such as test and measurement instrument 102 of FIG. 1) to the output of the circuit (Vout). Both the first probe and the second probe from the test and measurement instrument are connected to the common ground of the circuit. Two C capacitors in parallel work the same as a singular 2C capacitor. However, the depth of the notch obtainable in simulations like that shown in FIG. 11 is not the depth that can be achieved with real-world components. The best that the user can hope for in a hardware-based notch filter is 40 to 50 dB. The objective is not a notch filter but the rejection of a specific interfering frequency. Any filter that does not reject that interfering frequency because it misses the frequency or has too little rejection at that frequency is not much use.

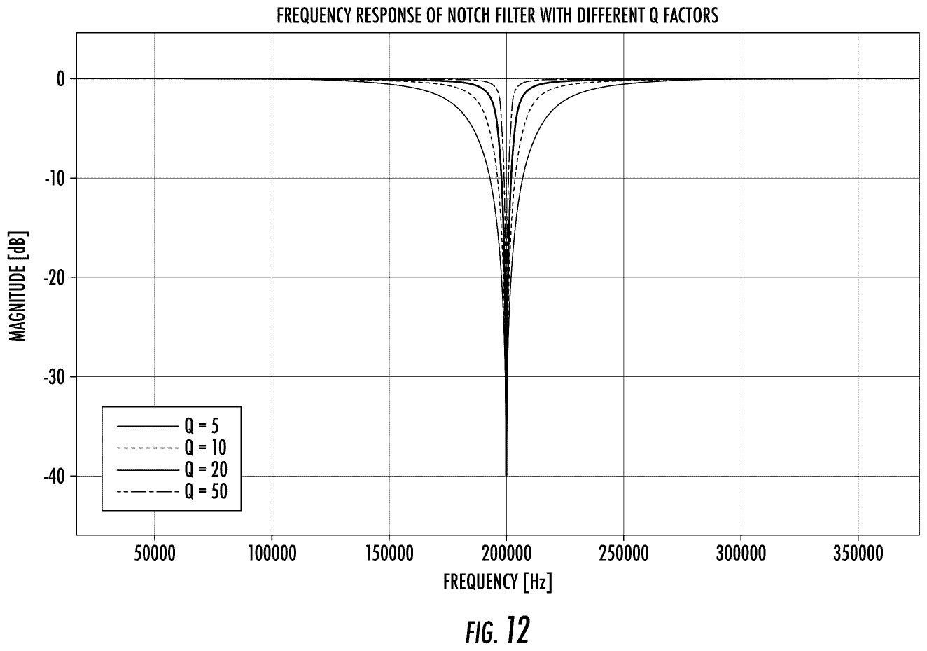

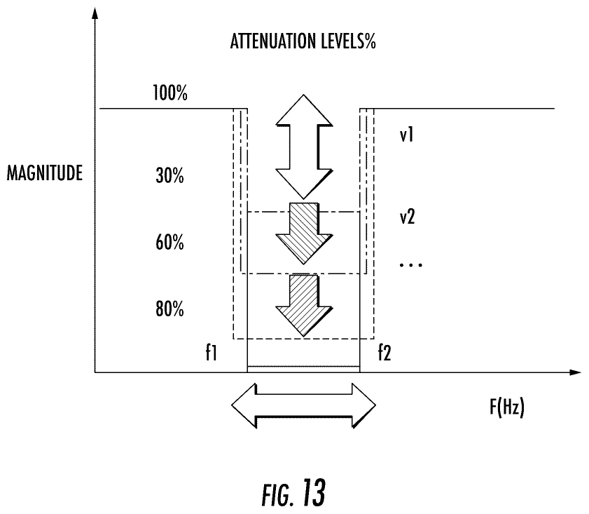

FIG. 12 illustrates a hardware-based notch filter with different Q values, in accordance with the present disclosure. The graph shown in FIG. 12 demonstrates the performance characteristics of the hardware-based notch filter, highlighting the relationship between Q-factor and attenuation depth. The graph shown in FIG. 12 shows the center frequency and the −3 dB points, clarifying the limitations of hardware-based filters in suppressing noise over a precise range.

The Q for a given notch filter is the −3-dB point, not the notch depth or a point 3 dB above the notch depth, as shown in FIG. 12. However, a software-based FFT based vertical notch filtering along with linear phase can achieve better performance. This vertical notch filtering combined with horizontal filtering gives a powerful and precise 2D filtering to emulate the impact of PDN designs.

FIG. 13 illustrates the vertical filtering levels of HSS jitter, in accordance with the present disclosure, which can be combined with horizontal filtering to achieve 2D filtering. The graph of FIG. 13 compares traditional horizontal-only filtering with the presently described approach, highlighting improvements in jitter suppression accuracy. As illustrated in FIG. 13, the vertical filtering of the present disclosure can be set at different levels, and while the levels shown in FIG. 13 are 100%, 30%, 60%, and 80%, the vertical filtering levels are not limited to these values and can be any value.

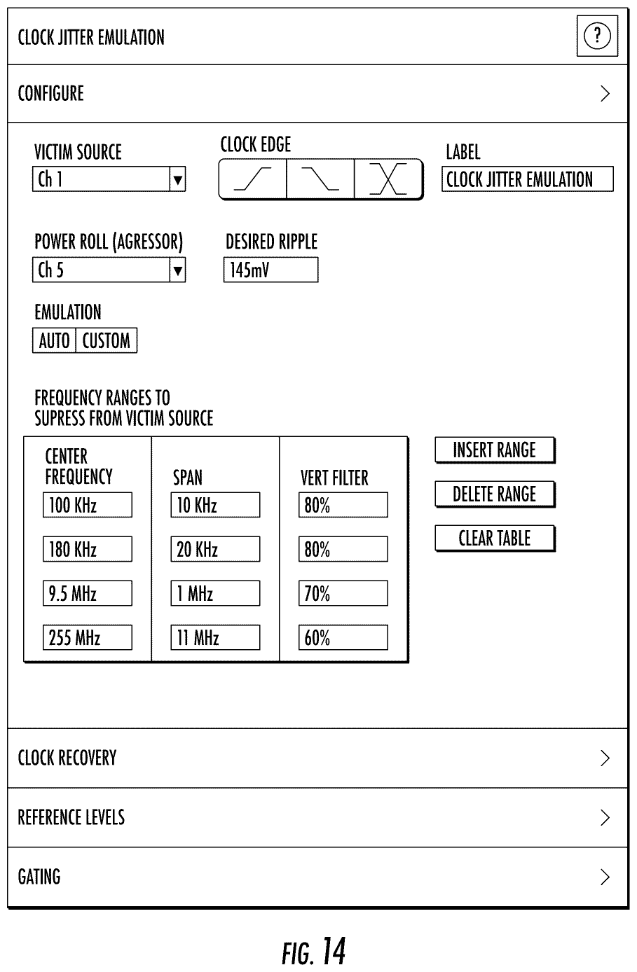

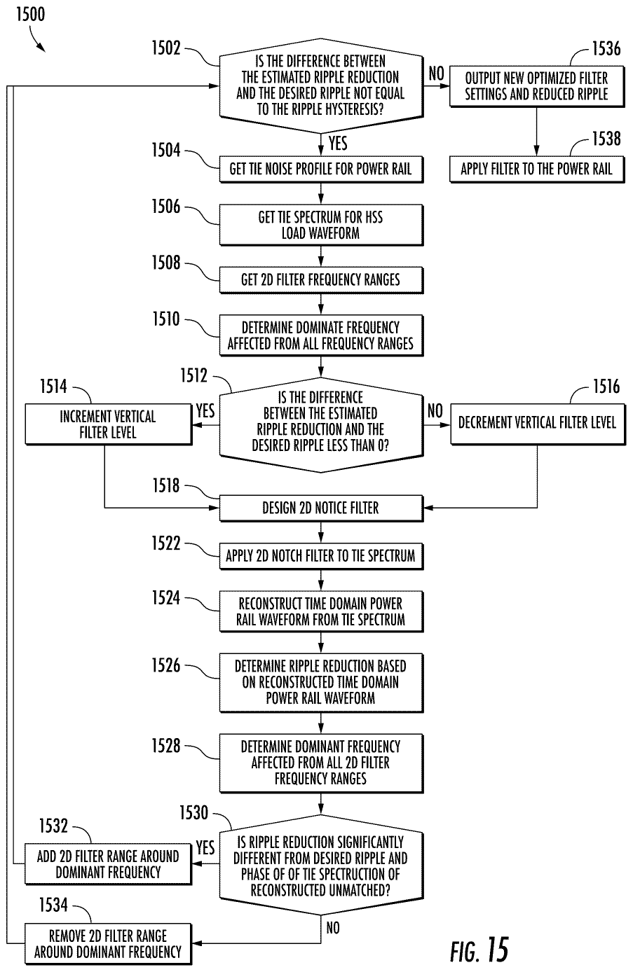

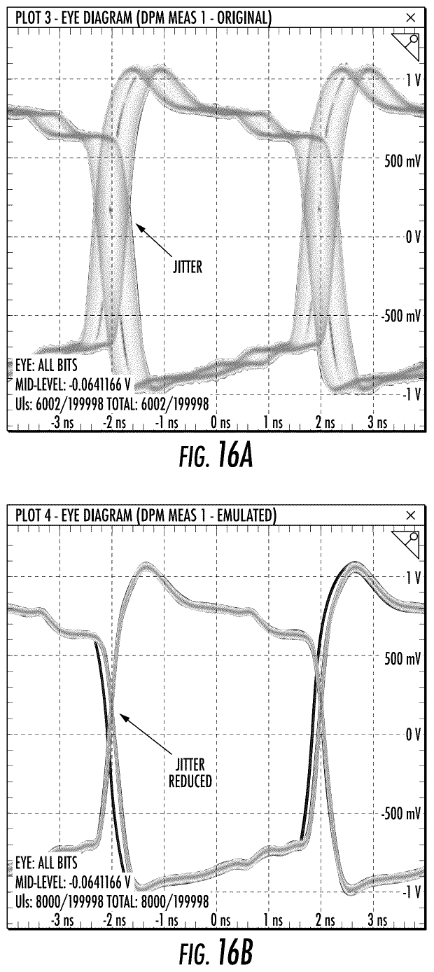

FIG. 14 illustrates measurement configuration with auto and custom ripple adjustment and 2D filters, in accordance with the present disclosure. The measurement configuration shown in FIG. 14 can be performed on a test and measurement instrument, such as the test and measurement instrument 102 of FIG. 1.

The measurement takes two sources: the power supply signal which is aggressor, and the high-speed signal which is victim. Accordingly, the measurement configuration requires the identification of the aggressor and the victim. The measurement configuration also takes in the desired ripple to be achieved along with HSS load, which can be the HSS analyzer 110 of FIG. 1. As shown in FIG. 14, the measurement configuration can also take in other parameters, such as center frequency, span, and vertical filtering.

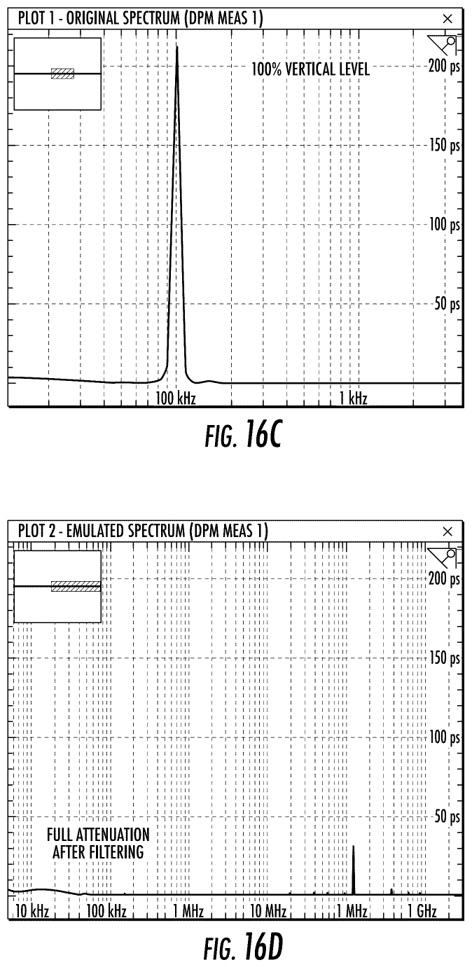

FIG. 15 is a flowchart illustrating operations for software-driven filtering, according to the present disclosure. The operations 1500 of FIG. 15 includes the identification of ripple frequencies, application of horizontal and vertical filtering, and iterative adjustment of the filter parameters to achieve the desired ripple outcome. The flowchart underscores the adaptability and precision of the system. Operations 1500 of FIG. 15 may be performed by the test and measurement instrument 102 of FIG. 1.

To optimize 2D filter configuration and achieve desired ripple reduction, operations 1500 may involve obtaining the 2D filter and targeted ripple parameters, specifically including frequency ranges (f1, f2), vertical attenuation levels (v1, v2), TIE spectra, and the specified RippleDesired value. While obtaining the 2D filter and targeted ripple parameters is not shown in FIG. 15,

Operations 1500 involve, at 1502, the test and measurement instrument determining whether the difference between the estimated reduced ripple value (Estimated RippleReduced) and the desired ripple value (RippleDesired) is different from the hysteresis ripple value (RippleHysteresis). In some examples, at initialization, the estimated reduced ripple value may be a value close to zero but not equal to zero and the desired ripple value may be configured by a user during measurement configuration, as shown in FIG. 14. Accordingly, initially, the difference between the estimated reduced ripple value and the desired ripple value is different from the hysteresis ripple value. While the difference between Estimated RippleReduced and RippleDesired does not equal RippleHysteresis, operations 1500 continue as follows:

At 1504, the test and measurement instrument retrieves the TIE noise profile for the power rail (aggressor).

At 1506, the test and measurement instrument obtains the TIE spectrum for the HSS load (victim) waveform. As mentioned, the HSS load can be the HSS analyzer 110 of FIG. 1.

At 1508, the test and measurement instrument identifies all potential 2D filter frequency ranges by evaluating combinations of aggressor and victim TIE spectra.

At 1510, the test and measurement instrument determines the dominant frequency affected among all ranges. In some examples, the dominant frequency can be the tallest peaks of the TIE spectrum after correlating with the FFT of the power rail voltage.

At 1512, the test and measurement instrument examines whether RippleReduced minus RippleDesired is less than zero. If RippleReduced minus RippleDesired is less than zero, the vertical filter level (VerticalFilterLevel) is increased by a defined step size at 1514; otherwise, VerticalFilterLevel is decreased accordingly at 1516. The vertical filter level can be set by the user during measurement configuration, as shown in FIG. 14. The step size may also be set by the user during measurement configuration, or by may be determined by the user at this point in operations 1500. In some examples, the step size may also be predetermined or preconfigured.

At 1518, a 2D notch filter is then designed using parameters f1, f2, v1, and v2. In some examples the 2D notch filter is an FFT band-stop filter within the frequency range f1 and f2 and having vertical attenuation based on v1, v2. In such examples, vertical attenuation based on v1, v2 is established based on the peak magnitude at the frequency range between f1 and f2 multiplied by a desired reduction factor. The desired reduction factor may be preconfigured or may be set by the user. In some examples, the value v2 is the maximum reduction value for the peaks and the value v1 is the minimum reduction value for the peaks.

At 1522, the test and measurement instrument applies the designed 2D notch filter to the TIE spectrum for HSS load.

At 1524, after application of the 2D notch filter, the test and measurement instrument reconstructs the time-domain power rail (aggressor) waveform from the filtered TIE spectrum.

At 1526, the test and measurement instrument measures RippleReduced on the reconstructed time-domain waveform.

At 1528, again, the test and measurement instrument identifies the dominant affected frequency from all 2D filter frequency ranges.

At 1530, the test and measurement instrument examines whether RippleReduced deviates from RippleDesired as defined by RippleHysteresis and/or whether the phase of the TIE spectrum is mismatched. If either are true, then at 1532, the test and measurement instrument adds a new 2D filter range centered around the dominant affected frequency from 1528; otherwise, at 1534, the procedure involves removing the 2D filter range surrounding the dominant frequency from 1528.

Ultimately, the optimized filter configuration and resultant RippleReduced are outputted at 1536 and the corresponding filter with the optimized filter configuration and resultant RippleReduced are applied to the power supply signal.

As described, a user can test at a desired ripple outcome which is directly proportional to PJ Jitter component. Based on desired ripple provided during configuration, the test and measurement instrument analyzes the jitter profile of victim signal and automatically add 2D filters into emulation. These auto populated 2D filters with appropriate vertical filter percentage are shown in the measurement configuration of FIG. 14. To auto-populate filter, the test and measurement instrument iteratively optimise the 2D filter settings until desired ripple is within the threshold of the test and measurement instrument. The user can modify or add or delete 2D filter ranges to fine-tune based on decoupling capacitor and EMI filters.

Internally, the power supply signal's FFT is used to find the ripple frequency, and since it is a linear relationship, percentage of ripple reduction can be applied to the dominant frequency of power supply FFT to find out the emulated ripple peak-to-peak.

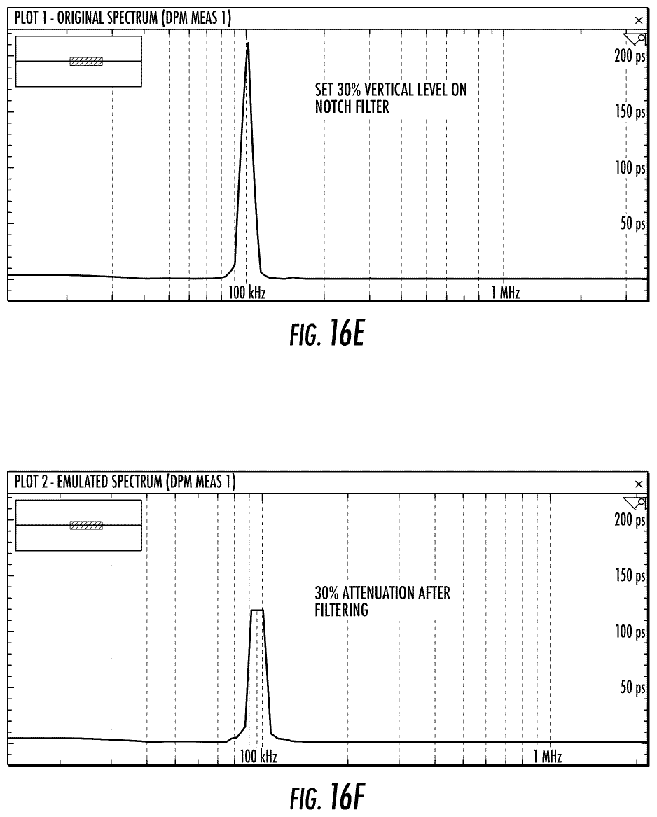

FIGS. 16A-F illustrates the vertical filter impact on controlled PJ reductions, in accordance with present disclosure. FIG. 16A is an eye diagram of high speed serial waveform before PSIJ emulation. FIG. 16B is an eye diagram after PSIJ Emulation. FIG. 16C is the TIE spectrum of high speed serial waveform before PSIJ emulation. FIG. 16D is the TIE spectrum after PSIJ emulation with 100% attenuation level filter setting. FIG. 16E is the TIE spectrum before PSIJ emulation of attenuation filtering. FIG. 16F is the TIE spectrum after PSIJ emulation with 30% attenuation level filter setting.

Table 3 below is a comparison chart between results corresponding to various combinations of frequency ranges (f1-f2) and vertical filter percentages (v1-v2), and their respective impact on phase jitter (PJ) and power rail ripple reduction. The chart quantifies improvements in ripple suppression and jitter reduction. These data demonstrate the performance characteristics of the disclosed filtering technique, specifically illustrating the relationship between filter parameters and the resulting improvements in jitter and ripple suppression.

TABLE 3

| V1-v2 (% reduction | | | | Ripple |
|---|---|---|---|---|
| from peak) | f1-f2 | PJ | | (input rail) |
| 0%-Full range | 260 K Hz-290 kHz | 10 | ps | 8 mV |
| From, peak to 10% | 260 K Hz-290 kHz | 8 | ps | 6 mV |
| 30% | 260 K Hz-290 kHz | 7.5 | ps | 5 mV |

As described herein, based on the settings, the filter suppresses the peak at a given frequency range, and hardware implementation with components may lead to small changes based on the filter response. Accordingly, the software-based filtering described herein can be implemented to emulate the hardware notch filter response, which will more closely emulate the hardware results.

The present disclosure offers a novel approach to correlating power supply ripple with high-speed signal jitter through a precise and customizable periodic noise filtering system. Unlike traditional hardware filters that are limited by Q-factor and non-linear phase response, the proposed solution combines vertical and horizontal filtering dimensions for comprehensive 2D filtering. This enables users to emulate PDN circuit behavior more accurately, quantify jitter suppression, and optimize power supply configurations. By leveraging advanced noise suppression techniques and real-time signal analysis, the present disclosure ensures superior signal integrity, reduces design iterations, and facilitates the development of reliable, high-performance electronic systems.

The foregoing description of the invention has been set merely to illustrate the invention and is not intended to be limiting. Since modifications of the disclosed embodiments incorporating the substance of the invention may occur to person skilled in the art, the invention should be construed to include everything within the scope of the invention.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the disclosed technologies are provided below. An embodiment of the technologies may include one or more, and any combination of, the examples described below.

Example 1 is a test and measurement instrument, may include: one or more test channels to connect to a device under test (DUT) and analyze signals generated by the DUT; and one or more processors configured to execute code to: measure a first ripple value of a power supply signal from a DUT; measure a first periodic jitter (PJ) value of a high-speed signal from a load device coupled to receive the power supply signal from the DUT, where the high-speed signal is based on the power supply signal; determine a first time interval error (TIE) spectrum from the first PJ value; filter the first TIE spectrum of the first PJ value to receive a second TIE spectrum corresponding to a second PJ value;determine a second ripple value by applying a jitter ratio based on the second PJ value and the first PJ value and a noise factor to the first ripple value; and apply the second ripple value to the power supply signal.

Example 2 is the test and measurement instrument of Example 1, where the code to filter the first PJ value to receive a second PJ value may include code when executed causes the one or more processors to filter the first PJ value using a notch filter.

Example 3 is the test and measurement instrument of Example 1 or Example 2, where the one or more processors are further configured to execute code to determine the noise factor.

Example 4 is the test and measurement instrument of any one of Example 1-3, where the code to determine the noise factor may include code when executed causes the one or more processors to: capture a high speed clock signal; determine a first PJ component of known value; apply the first PJ component to the captured high-speed clock signal to generate a waveform with the first PJ component; apply a filter to the waveform to generate a filtered waveform; measure a resulting reduced ripple component of the filtered waveform; and generate a second waveform using the resulting reduced ripple component.

Example 5 is the test and measurement instrument of any one of Example 1-4, where the one or more processors are further configured to display the second ripple value to a user, thereby enabling visualization of a correlation between percentage ripple reduction and jitter suppression in the high-speed signal.

Example 6 is the test and measurement instrument of any one of Example 1-5, where the high-speed signal is a high-speed serial signal.

Example 7 is the test and measurement instrument of any one of Example 1-6, where the code to filter the first TIE spectrum of the first PJ value may include code when executed causes the one or more processors to: iteratively optimize filter settings for the first TIE spectrum until a desired ripple is within a threshold of the test and measurement instrument.

Example 8 is a method of operating a test and measurement instrument, may include: measuring a first ripple value of a power supply signal from a device under test (DUT); measuring a first periodic jitter (PJ) value of a high-speed signal from a load device coupled to receive the power supply signal from the DUT, where the high-speed signal is based on the power supply signal; determining a first time interval error (TIE) spectrum from the first PJ value; filtering the first TIE spectrum of the first PJ value to receive a second TIE spectrum corresponding to a second PJ value; determining a second ripple value by applying a jitter ratio based on the filtered PJ value and the actual PJ value and a noise factor to the first ripple value; and applying the second ripple value to the power supply signal.

Example 9 is the method of Example 8, where filter the first PJ value to receive a second PJ value may include filtering the first PJ value using a notch filter.

Example 10 is the method of Example 8 or Example 9, further may include determining the noise factor.

Example 11 is the method of any one of Example 8-10, further may include: capturing a high-speed clock signal; determining a first PJ component of known value; applying the first PJ component to the captured high-speed clock signal to generate a waveform with the first PJ component; applying a filter to the waveform to generate a filtered waveform; measuring a resulting reduced ripple component of the filtered waveform; and generating a second waveform using the resulting reduced ripple component.

Example 12 is the method of any one of Example 8-11, where the high-speed clock signal is transmitted from the load device.

Example 13 is the method of any one of Example 8-12, further may include displaying the second ripple value to a user, thereby enabling visualization of a correlation between percentage ripple reduction and jitter suppression in the high-speed signal.

Example 14 is the method of any one of Example 8-13, where the high-speed signal is a high-speed serial signal.

Example 15 is a test and measurement instrument, may include one or more test channels to connect to a device under test (DUT) and analyze signals generated by the DUT; and one or more processors configured to execute code to: acquire a power supply signal from a DUT and a high-speed signal from a load device, where the high-speed signal is based on the power supply signal, where the high-speed signal may include jitter and the power supply signal may include ripple; generate a vertical filter based on a frequency range of the high-speed signal, where the vertical filter is configured to vertically attenuate a peak magnitude in the frequency range by a reduction factor; apply the vertical filter to a time interval error (TIE) spectrum of the high-speed signal; and reconstruct a filtered power supply signal from a vertically-filtered high-speed signal based on the filtered TIE spectrum to correlate the jitter of the high-speed signal to the ripple of the power supply signal.

Example 16 is the test and measurement instrument of Example 15, where the vertical filter is two dimensional notch filter.

Example 17 is the test and measurement instrument of Example 15 or Example 16, where the code to generate the vertical filter may include code when executes causes the one or more processors to generate a band stop filter for horizontal and vertical filtering using the frequency range of the high-speed signal.

Example 18 is the test and measurement instrument of any one of Example 15-17, where the one or more processors are further configured to execute code to adjust the reduction factor of the vertical filter.

Example 19 is the test and measurement instrument of any one of Example 15-18, where the one or more processors are further configured to recalculate ripple to verify convergence toward a desired ripple value.

Example 20 is the test and measurement instrument of any one of Example 15-19, where the one or more processors are further configured to execute code to iteratively optimize the vertical filter to achieve a desired ripple value in an emulation of the high-speed signal.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

Although specific aspects of the disclosure have been illustrated and described for purposes of illustration, it will be understood that various modifications may be made without departing from the spirit and scope of the disclosure.

What is claimed is:

1. A test and measurement instrument, comprising:
one or more test channels to connect to a device under test (DUT) and analyze signals generated by the DUT; and
one or more processors configured to execute code to:
measure a first ripple value of a power supply signal from a DUT;
measure a first periodic jitter (PJ) value of a high-speed signal from a load device coupled to receive the power supply signal from the DUT, wherein the high-speed signal is based on the power supply signal;
determine a first time interval error (TIE) spectrum from the first PJ value;
filter the first TIE spectrum of the first PJ value to receive a second TIE spectrum corresponding to a second PJ value; determine a second ripple value by applying a jitter ratio based on the second PJ value and the first PJ value and a noise factor to the first ripple value; and
apply the second ripple value to the power supply signal.

2. The test and measurement instrument of claim 1, wherein the code to filter the first PJ value to receive a second PJ value comprises code when executed causes the one or more processors to filter the first PJ value using a notch filter.

3. The test and measurement instrument of claim 1, wherein the one or more processors are further configured to execute code to determine the noise factor.

4. The test and measurement instrument of claim 3, wherein the code to determine the noise factor comprises code when executed causes the one or more processors to:
capture a high speed clock signal;
determine a first PJ component of known value;
apply the first PJ component to the captured high-speed clock signal to generate a waveform with the first PJ component;
apply a filter to the waveform to generate a filtered waveform;
measure a resulting reduced ripple component of the filtered waveform; and
generate a second waveform using the resulting reduced ripple component.

5. The test and measurement instrument of claim 1, wherein the one or more processors are further configured to display the second ripple value to a user, thereby enabling visualization of a correlation between percentage ripple reduction and jitter suppression in the high-speed signal.

6. The test and measurement instrument of claim 1, where the high-speed signal is a high-speed serial signal.

7. The test and measurement instrument of claim 1, wherein the code to filter the first TIE spectrum of the first PJ value comprises code when executed causes the one or more processors to:
iteratively optimise filter settings for the first TIE spectrum until a desired ripple is within a threshold of the test and measurement instrument.

8. A method of operating a test and measurement instrument, comprising:
measuring a first ripple value of a power supply signal from a device under test (DUT);
measuring a first periodic jitter (PJ) value of a high-speed signal from a load device coupled to receive the power supply signal from the DUT, wherein the high-speed signal is based on the power supply signal;
determining a first time interval error (TIE) spectrum from the first PJ value;
filtering the first TIE spectrum of the first PJ value to receive a second TIE spectrum corresponding to a second PJ value;
determining a second ripple value by applying a jitter ratio based on the filtered PJ value and the actual PJ value and a noise factor to the first ripple value; and
applying the second ripple value to the power supply signal.

9. The method of claim 8, wherein filter the first PJ value to receive a second PJ value comprises filtering the first PJ value using a notch filter.

10. The method of claim 8, further comprising determining the noise factor.

11. The method of claim 10, further comprising:
capturing a high-speed clock signal;
determining a first PJ component of known value;
applying the first PJ component to the captured high-speed clock signal to generate a waveform with the first PJ component;
applying a filter to the waveform to generate a filtered waveform;
measuring a resulting reduced ripple component of the filtered waveform; and
generating a second waveform using the resulting reduced ripple component.

12. The method of claim 11, wherein the high-speed clock signal is transmitted from the load device.

13. The method of claim 8, further comprising displaying the second ripple value to a user, thereby enabling visualization of a correlation between percentage ripple reduction and jitter suppression in the high-speed signal.

14. The method of claim 8, where the high-speed signal is a high-speed serial signal.

15. A test and measurement instrument, comprising
one or more test channels to connect to a device under test (DUT) and analyze signals generated by the DUT; and
one or more processors configured to execute code to:
acquire a power supply signal from a DUT and a high-speed signal from a load device, wherein the high-speed signal is based on the power supply signal, wherein the high-speed signal comprises jitter and the power supply signal comprises ripple;
generate a vertical filter based on a frequency range of the high-speed signal, wherein the vertical filter is configured to vertically attenuate a peak magnitude in the frequency range by a reduction factor;
apply the vertical filter to a time interval error (TIE) spectrum of the high-speed signal; and
reconstruct a filtered power supply signal from a vertically-filtered high-speed signal based on the filtered TIE spectrum to correlate the jitter of the high-speed signal to the ripple of the power supply signal.

16. The test and measurement instrument of claim 15, wherein the vertical filter is two dimensional notch filter.

17. The test and measurement instrument of claim 15, wherein the code to generate the vertical filter comprises code when executes causes the one or more processors to generate a band stop filter for horizontal and vertical filtering using the frequency range of the high-speed signal.

18. The test and measurement instrument of claim 15, wherein the one or more processors are further configured to execute code to adjust the reduction factor of the vertical filter.

19. The test and measurement instrument of claim 15, wherein the one or more processors are further configured to recalculate ripple to verify convergence toward a desired ripple value.

20. The test and measurement instrument of claim 15, wherein the one or more processors are further configured to execute code to iteratively optimize the vertical filter to achieve a desired ripple value in an emulation of the high-speed signal.
